(19) United States
(12) Patent Application Publication
(10) Pub. No.: US 2026/0059726 A1
(43) Pub. Date: Feb. 26, 2026

(54) POWER CONVERSION DEVICE

(71) Applicant: DENSO CORPORATION, Kariya-city (JP)

(72) Inventors: Chie MIZOGUCHI, Kariya-city (JP); Michinari Fukuoka, Kariya-city (JP)

(73) Assignee: DENSO CORPORATION, Kariya-city (JP)

(21) Appl. No.: 19/377,537

(22) Filed: Nov. 3, 2025

Related U.S. Application Data
(63) Continuation of application No. PCT/JP2024/015928, filed on Apr. 23, 2024.

(30) Foreign Application Priority Data
May 16, 2023 (JP) 2023-081066

(51) Int. Cl. H05K 7/20

(52) U.S. Cl. CPC H05K 7/20927

(57) ABSTRACT

A power conversion device has heat generating components mounted to a base part, which is a component mounting part, side by side, and a cooling part that is integrally provided to the base part and cools the heat generating components. The cooling part has a flow passage formation part that forms a refrigerant flow passage in a direction in which the heat generating components are arranged, and a fin that extends from an upstream side to a downstream side in the refrigerant flow passage. The heat generating portion on the upstream side and the heat generating portion on the downstream side of the heat generating portions in the cooling part differ in fin structure, and at the heat generating portion on the downstream side, the number of fins separated from each other in a refrigerant circulation direction is larger than that at the heat generating portion on the upstream side.

### CROSS-REFERENCE TO RELATED APPLICATION

The present application is based on Japanese Patent Application No. 2023-081066 filed on May 16, 2023, the description of which is incorporated herein by reference.

### BACKGROUND

### (Technical Field)

The present disclosure relates to a power conversion device.

### (Related Art)

Power conversion devices such as a boost converter and an inverter have a plurality of heat generating components including a reactor and a semiconductor device. Various techniques for cooling the heat generating components have been proposed.

### SUMMARY

An aspect of the present disclosure provides a power conversion device having a plurality of heat generating components that are mounted to a base part, which is a component mounting part, side by side, and a cooling part that is integrally provided to the base part and cools the plurality of heat generating components, wherein the cooling part has a flow passage formation part that forms a refrigerant flow passage in a direction in which the plurality of heat generating components are arranged, and a fin that extends from an upstream side to a downstream side in the refrigerant flow passage, portions corresponding to the heat generating components in the base part are respectively heat generating portions, and the heat generating portion on the upstream side and the heat generating portion on the downstream side of the heat generating portions in the cooling part differ in fin structure, and at the heat generating portion on the downstream side, the number of fins separated from each other in a refrigerant circulation direction is larger than that at the heat generating portion on the upstream side.

### BRIEF DESCRIPTION OF THE DRAWINGS

In the accompanying drawings:

FIG. 1 is a longitudinal sectional view illustrating a schematic configuration of a power conversion device;

FIG. 2 is a plan view illustrating a configuration of a cooling part;

FIG. 3 is a drawing illustrating a boundary layer formed on a side surface of a fin;

FIG. 4 is a drawing illustrating a modification in which part of the configuration of the cooling part is modified;

FIG. 5 is a plan view illustrating a more specific configuration of reactors;

FIG. 6 is a view illustrating a configuration of a cooling part of a second embodiment;

FIG. 7 is a view illustrating a configuration of a cooling part of a third embodiment; and

FIG. 8 is a view illustrating a configuration of a cooling part of a fourth embodiment.

### DETAILED DESCRIPTION OF THE PREFERRED EMBODIMENTS

Power conversion devices such as a boost converter and an inverter have a plurality of heat generating components including a reactor and a semiconductor device. Various techniques for cooling the heat generating components have been proposed. For example, Japanese Patent No.4985382 discloses a technique in which, in a cooling pipe disposed on and being in close contact with semiconductor elements, fin groups including a plurality of fins for improving the cooling efficiency of portions, with which the semiconductor elements are in close contact, are provided so as to correspond to the semiconductor elements, and the center of the fin group is disposed on the upstream side of a refrigerant flow passage with respect to the center of the semiconductor element corresponding to the fin group.

However, when a plurality of heat generating components are cooled by a refrigerant flowing through a refrigerant flow passage, the degree of cooling differs between the heat generating components on the upstream side of the refrigerant flow passage and the heat generating components on the downstream side of the refrigerant flow passage, whereby there is a concern that temperature differences may occur between the heat generating components. That is, since the refrigerant flowing through the refrigerant flow passage becomes higher in temperature approaching the downstream side, there is a concern that desired cooling capability cannot be obtained in the heat generating components on the downstream side.

In view of the above problem, the present disclosure has an object of appropriately cooling heat generating components also in a power conversion device having a plurality of heat generating components.

Hereinafter, embodiments of a power conversion device according to the present disclosure will be described with reference to the drawings. The present embodiments describe power conversion devices used as a boost converter that boosts voltage of an in-vehicle battery in a power supply system installed in an electrically-driven vehicle such as a hybrid automobile or an electric automobile.

### (First embodiment)

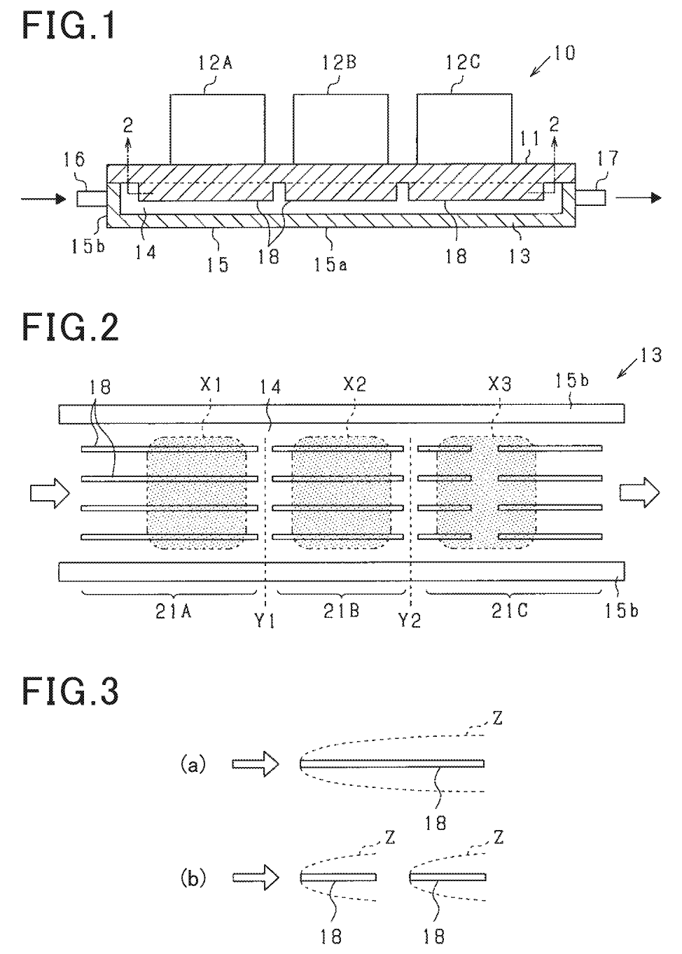

As illustrated in FIG. 1, a power conversion device 10 includes a base part 11 having a plate shape and a plurality of reactors 12 arranged on the base part 11 side by side. In FIG. 1, the three reactors 12 arranged laterally side by side are indicated as reactors 12A to 12C. The base part 11 is formed of, for example, a metallic material such as aluminum. The base part 11 needs to configure part of a housing of the power conversion device 10 and serves as a component mounting part to which the plurality of reactors 12 are mounted. As is well known, the reactor 12 has a core and a coil wound around the core. Each of the reactors 12 has a single-phase reactor having one coil or a multiple-phase reactor having a plurality of coils. In the present embodiment, the reactor 12 corresponds to a heat generating component.

In the power conversion device 10, a cooling part 13 cooling the reactors 12 is provided on one of two sides of the base part 11 in the thickness direction opposite to the side on which the reactors 12 are provided. The cooling part 13 is integrally provided to the base part 11, and has a water-cooling structure (liquid cooling structure) that circulates a refrigerant such as cooling water to cool the reactors 12. The cooling part 13 has a flow passage formation part 15 that forms a refrigerant flow passage 14. The flow passage formation part 15 is mounted to the base part 11, whereby the refrigerant flow passage 14 is formed as a closed space between the base part 11 and the flow passage formation part 15. In FIG. 1, the left side of the drawing is the upstream side, and the right side of the drawing is the downstream side. The uppermost stream part of the cooling part 13 is provided with an inlet part 16, and the lowermost stream part of the cooling part 13 is provided with an outlet part 17. The refrigerant flows in through the inlet part 16, and is subjected to heat exchange in the refrigerant flow passage 14, thereafter flowing out through the outlet part 17.

The flow passage formation part 15 has a bottom plate part 15a and a peripheral wall part 15b. The base part 11 and the bottom plate part 15a are separated by the peripheral wall part 15b, and the refrigerant flow passage 14 is formed therebetween. The inlet part 16 is provided at one end of the peripheral wall part 15b in the arrangement direction of the reactors 12, and the outlet part 17 is provided at the other end of the peripheral wall part 15b. However, instead of this configuration, the configuration in which the peripheral wall part is provided at the base part 11 may be used. In this case, the inlet part 16 and the outlet part 17 may be provided to the peripheral wall part extending from the base part 11. The peripheral wall part surrounding the refrigerant flow passage 14 may be provided to at least any of the base part 11 and the flow passage formation part 15.

Although not shown, the refrigerant flow passage 14 is configured to be connected with an external circulation path that circulates a refrigerant. The external circulation path is provided with, for example, an electric pump and a heat release device such as a radiator. Driving the pump circulates the refrigerant through the circulation path and the refrigerant flow passage 14 of the power conversion device 10.

A plurality of fins 18 extending from the upstream side to the downstream side are provided on the refrigerant flow passage 14 side of the two sides of the base part 11 in the thickness direction. The fin 18 has a flat plate shape. The base part 11 functions as a heatsink.

FIG. 2 is a plan view illustrating a configuration of the cooling part 13. FIG. 2 corresponds to a line 2-2 sectional view of FIG. 1. In FIG. 2, a plurality of heat generating portions X (X1 to X3) due to the reactors 12 in the base part 11 are indicated by broken lines. The heat generating portions X are portions to which the reactors 12 are mounted in the base part 11 and are targets to be cooled. Herein, the heat generating portions X corresponding to the three reactors 12A to 12C are respectively indicated by the heat generating portions X1, X2, X3. Regarding positions on the refrigerant flow passage 14, the heat generating portion X1 is a heat generating portion on the uppermost stream side, the heat generating portion X2 is a heat generating portion at the intermediate position, and the heat generating portion X3 is a heat generating portion on the lowermost stream side.

In FIG. 2, a pair of peripheral wall part 15b are provided at a predetermined distance, and the refrigerant flow passage 14 is formed therebetween. The refrigerant flow passage 14 is provided so as to overlap with the heat generating portions X1 to X3. The refrigerant flow passage 14 has no folding on the way thereof and allows the refrigerant to flow in one direction. The plurality of fins 18 extend in the refrigerant flow passage 14 from the upstream side to the downstream side and are arranged in the width direction of the refrigerant flow passage 14 side by side in parallel.

The fins 18 are divided at positions Y1, Y2 between the heat generating portions X1 to X3 in the direction in which the refrigerant circulates. Hence, fin groups 21 each of which includes a plurality of fins 18 are respectively provided at the heat generating portions X1 to X3. In the present embodiment, the fin groups 21 include first to third fin groups 21A to 21C. The fin groups 21A to 21C are separated from each other in the refrigerant circulation direction. The first fin group 21A is a fin group provided at the heat generating portion X1, the second fin group 21B is a fin group provided at the heat generating portion X2, and the third fin group 21C is a fin group provided at the heat generating portion X3. Each of the fin groups 21A to 21C is configured by a plurality of fins 18 arranged in a row in the direction orthogonal to the refrigerant circulation direction. It is noted that, in FIG. 2, although the number of fins in each row arranged in the direction orthogonal to the refrigerant circulation direction is four, this is an example. Five or more fins 18 may be arranged.

Of the fin groups 21A to 21C, the first and second fin groups 21A, 21B and the third fin group 21C differ in fin structure. In the third fin group 21C, the number of divisions of the fin in the refrigerant circulation direction is larger than that in the other fin groups 21A, 21B. Specifically, although the number of divisions of the fin in the refrigerant circulation direction at the heat generating portions X1, X2 in the first and second fin groups 21A, 21B is zero (the number of fins is one), the number of divisions of the fin in the refrigerant circulation direction at the heat generating portion X3 in the third fin group 21C is one (the number of fins is two). That is, in the cooling part 13, at the heat generating portion X3 on the downstream side, the number of fins separated from each other in the refrigerant circulation direction is larger than those at the heat generating portions X1, X2 on the upstream side.

In addition, in the third fin group 21C (the heat generating portion X3 on the downstream side), lengths the fins 18 are shorter than those in the fin groups 21A, 21B on the upstream side. In the third fin group 21C, two rows of a plurality (four in the drawing) of fins 18 arranged in the width direction of the refrigerant flow passage 14 are provided in the refrigerant circulation direction.

It is noted that, in FIG. 2, at the two heat generating portions X1, X2 on the upstream side, instead of dividing the fin group 21 into two between the heat generating portions X1 and X2, one continuous fin group 21 may be provided. That is, the first and second fins may be integrated into one.

In the cooling part 13 illustrated in FIG. 2, in the third fin group 21C, since the number of fins in the refrigerant circulation direction is larger than that on the upstream side, and the lengths of the fins 18 are shorter than those of the fins 18 on the upstream side, a boundary layer formed on a side surface of the fin becomes smaller, whereby heat-transfer coefficients of the fins 18 are suppressed from lowering. That is, when the fin 18 having a flat plate shape is present in the flow of the refrigerant, as illustrated in FIG. 3(a), a boundary layer Z is formed along the direction of the flow from the tip of the fin 18, and the boundary layer Z is thickened approaching the downstream side. As the boundary layer Z is thickened, the heat-transfer coefficient lowers. In this regard, as illustrated in FIG. 3(b), dividing the fin 18 in the refrigerant circulation direction and shortening the length of the fin 18 can prevent the boundary layer Z from being thickened, whereby the boundary layer Z can be kept thin. Hence, in the third fin group 21C, the heat-transfer coefficient is suppressed from lowering, whereby eventually cooling capability can be improved.

In FIG. 2, at the two heat generating portions X1, X2 on the upstream side, that is, the portions corresponding to the back sides of the two reactors 12A, 12B on the upstream side (the opposite sides with the base part 11 being interposed), the fin groups 21 are not separated in the refrigerant circulation direction, but are separated in the refrigerant circulation direction only at the portion corresponding to the portion between the heat generating portions X1 and X2. In contrast, at the heat generating portion X3 on the lowermost stream side, that is, the portion corresponding to the back side of the reactor 12C on the lowermost stream side, the fin group 21 is separated in the refrigerant circulation direction. Hence, at the heat generating portions X1, X2, the degree of breakage of the boundary layer Z becomes relatively low, which suppresses heat exchange at the fin groups 21, whereby the refrigerant temperature is suppressed from increasing. In contrast, at the heat generating portion X3, the boundary layer Z becomes thinner than those at the heat generating portions X1, X2 on the upstream side. Hence, the decrease of the cooling capability due to the increase of the refrigerant temperature at the heat generating portions X1, X2 on the upstream side can be compensated for by the increase of the cooling capability caused by blocking the growth of the boundary layer thickness.

Herein, of the fin groups 21A to 21C, the cooling capability of only the third fin group 21C on the lowermost stream side can be increased by dividing the fins 18. If the two heat generating portions X1, X2 on the upstream side and the heat generating portion X3 on the lowermost stream side are compared, the cooling capability of only the heat generating portion X3 on the lowermost stream side is increased. In this case, when the refrigerant passes through the heat generating portions X1, X2 on the upstream side in the refrigerant flow passage 14, the refrigerant temperature increases due to heat exchange. Even if the difference between the temperature of the heat generating portion X3 on the lowermost stream side and the refrigerant temperature has become small due to the increase of the refrigerant temperature, the decrease of the cooling efficiency can be compensated for by the fin structure different from that on the upstream. Hence, the cooling rate of the whole cooling part is equalized.

From the viewpoint of the third fin group 21C on the lowermost stream side, it can also be said that the cooling efficiency is lowered in the first fin group 21A on the uppermost stream side.

As illustrated in FIG. 2, at the heat generating portions X1 to X3, straight fins having a straight plate shape are provided as the fins 18 of the fin groups 21A to 21C. In addition, the fin 18 of the first fin group 21A on the uppermost stream side is provided so as to include a straight surplus portion extending to the upstream side from the heat generating portion X1. The fin 18 of the third fin group 21C on the lowermost stream side is provided so as to include a straight surplus portion extending to the downstream side from the heat generating portion X3. Hence, since the flow of the refrigerant is controlled in the vicinity of the inlet and the outlet of the refrigerant flow passage 14, the refrigerant favorably circulates, whereby the cooling efficiency of the whole flow passage can be ensured. It is noted that although the fin groups 21A, 21C on the uppermost stream side and the lowermost stream side have surplus portions on the upstream side and the downstream side of the heat generating portions X1, X3, the surplus portions are longer on the upstream side of the heat generating portion X1 and the downstream side of the heat generating portion X3.

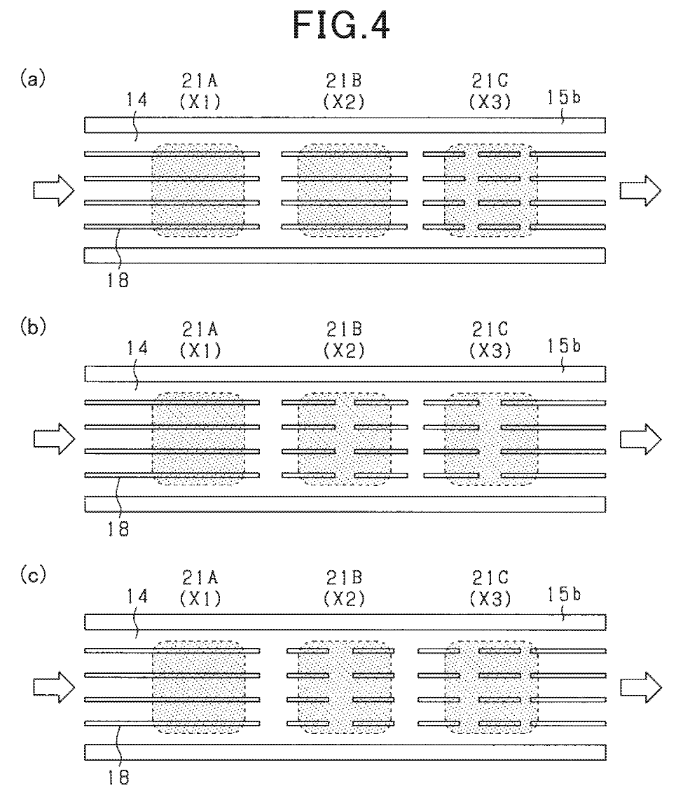

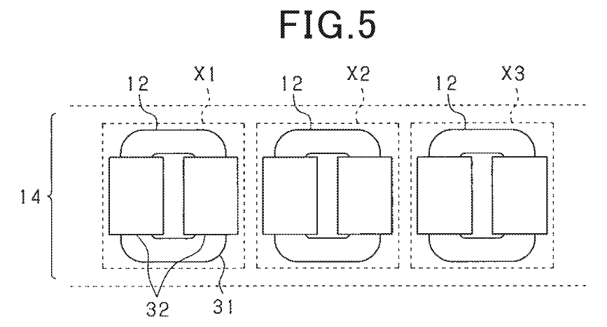

FIG. 4 illustrates a modification in which part of the configuration of the cooling part 13 in FIG. 2 is modified.

In FIG. 4(a), as in FIG. 2, the first and second fin groups 21A, 21B and the third fin group 21C differ from each other in fin structure. However, the fin structure of the third fin group 21C is modified from that in FIG. 2, so that the number of divisions of the fin in the refrigerant circulation direction is two (the number of fins is three).

In FIG. 4(b), the first fin group 21A and the second and third fin groups 21B, 21C differ from each other in fin structure. Specifically, in the first fin group 21A, the number of divisions of the fin in the refrigerant circulation direction at the heat generating portion X1 is zero (the number of fins is one), whereas, in the second and third fin groups 21B, 21C, the number of divisions of the fin in the refrigerant circulation direction at the heat generating portions X2, X3 is one (the number of fins is two). Also in the present configuration, as in the configuration in FIG. 2, in the cooling part 13, at the heat generating portions on the downstream side (heat generating portions X2, X3), the number of fins separated in the refrigerant circulation direction is larger than that at the heat generating portion on the upstream side (heat generating portion X1). In addition, the length of the fin 18 in the second and third fin groups 21B, 21C is shorter than that in the first fin group 21A on the upstream side.

In FIG. 4(c), the fin groups 21A to 21C differ from each other in fin structure. Specifically, in the first fin group 21A, the number of divisions of the fin in the refrigerant circulation direction at the heat generating portion X1 is zero (the number of fins is one). In the second fin group 21B, the number of divisions of the fin in the refrigerant circulation direction at the heat generating portion X2 is one (the number of fins is two). In the third fin group 21C, the number of divisions of the fin in the refrigerant circulation direction at the heat generating portion X3 is two (the number of fins is three). Also in the present configuration, as in the configuration in FIG. 2, in the cooling part 13, at the heat generating portions on the downstream side, the number of fins separated in the refrigerant circulation direction is larger than that at the heat generating portion on the upstream side.

According to the present embodiment described above in detail, the following superior effects can be obtained.

In the power conversion device 10, when the plurality of reactors 12 are cooled in predetermined order by the refrigerant flowing through the refrigerant flow passage 14 of the cooling part 13, there is a concern that the cooling capability of the reactor 12 on the downstream side of the refrigerant flow passage 14 becomes lower than that of the reactor 12 on the upstream side of the refrigerant flow passage 14. Focusing on this point, of the heat generating portions X1 to X3 corresponding to the respective reactors 12, fin structures are differentiated between the heat generating portion on the upstream side and the heat generating portion on the downstream side, and the number of fines separated from each other in the refrigerant circulation direction is made larger at the heat generating portion on the downstream side than at the heat generating portion on the upstream side. Hence, the cooling efficiency of the heat generating portion on the downstream is increased compared with that at the heat generating portion on the upstream side. As a result, in the power conversion device 10 having the plurality of reactors 12, the reactors 12 can be appropriately cooled.

Of the fin groups 21A to 21C, in the third fin group 21C (heat generating portion X3) on the lowermost side, the number of fins in the refrigerant circulation direction is made larger than those on the upstream side, and the length of the fin 18 is made shorter than those of the fin groups on the upstream side (heat generating portions X1, X2). In this case, in the third fin group 21C on the lowermost side, the growth of the boundary layer can be suppressed, whereby the cooling efficiency can be ensured.

As illustrated in FIG. 4(c), the number of fins in the refrigerant circulation direction increases in order of the first fin group 21A, the second fin group 21B, and the third fin group 21C (i.e., in order of the heat generating portion X1 on the uppermost stream side, the heat generating portion X2 at the intermediate position, and the heat generating portion X3 on the lowermost stream side). In this case, with respect to the heat generating portion X2 at the intermediate position, the cooling efficiency of the heat generating portion X1 on the uppermost stream side is decreased, and the cooling efficiency of the heat generating portion X3 on the lowermost stream side is increased, whereby a configuration suitable for equalizing the degrees of cooling the reactors 12A to 12C of the power conversion device 10 can be achieved.

The plurality of reactors 12 (12A to 12C) are arranged side by side in order from the upstream side of the refrigerant flow passage 14 to the downstream side thereof, on the surface opposite to the surface, on which the cooling part 13 is provided, of the base part 11 of the power conversion device 10. In the power conversion device 10, the plurality of reactors 12 utilizing the same refrigerant flow passage 14 can be uniformly cooled. It can be said that, recently, this is especially significant in practical use. That is, in electric automobiles, driving force required for an electric motor tends to increase, and the amount of heat generation in the reactor 12 increases as electric power (current) increases, whereas the outer shape and the arrangement area of the reactor 12 are difficult to increase because weight reduction and miniaturization are strongly required. Hence, the amount of heat to be cooled per the arrangement area of the reactor 12 is larger than before. In addition, of the heat generating components configuring the power conversion device 10, the amount of heat generation and the arrangement area of the reactor 12 tend to be larger than those of semiconductor elements such as an inverter. Furthermore, the reactors are often adjacently arranged side by side. Hence, the temperature of the portion at which the plurality of reactors 12 are arranged easily become high, which leads heat to be easily filled.

The technique of the present embodiment controls the increase of the refrigerant temperature and the thickness of the boundary layer so as to compensate for the decrease of the cooling capability due to the increase of the refrigerant temperature with the increase of the cooling capability caused by blocking the growth of the boundary layer thickness. Hence, an object of ensuring a temperature environment in which the reactor 12 used for the power conversion device 10 appropriately functions can be achieved.

FIG. 5 illustrates a more specific configuration of the reactors 12 illustrated in FIG. 1 and FIG. 2. In FIG. 5, each of the reactors 12 has a core 31 having a substantially ring shape and a pair of coils 32 wound around the core 31. The pair of coils 32 is disposed in a state of being separated from each other in the direction in which the reactors 12 are arranged (the horizontal direction in the drawing). An inter-coil gap is formed between the pair of coils 32. The heat generating portion X is an area on which the reactors 12 is approximately projected in a planar view (an area including a projection part).

In this case, at the portions of the respective heat generating portions X corresponding to the coils 32, the amount of heat generation is large. Hence, as illustrated in FIG. 2 and FIG. 4, providing a portion, at which the fins 18 are divided, at a position between the pair of coils 32 (inter-coil gap) breaks the growth of the boundary layer in the refrigerant flow passage 14 at a portion corresponding to the coil 32, which is a heat source, whereby the cooling efficiency can be increased. It is noted that although the heat generating portion X (inside the broken line frame) has a part in which there is no coil 32, in the base part 11, heat concentrates in the heat generating portion X due to the heat transfer in the base part 11, whereby the temperature of the heat generating portion X becomes high. In addition, depending on the arrangement direction of the pair of coils 32 of the reactor 12, there is a case in which the whole of the heat generating portion X (inside the broken line frame) becomes a heat generating portion.

Hereinafter, other embodiments in which part of the first embodiment is modified will be described.

### (Second embodiment)

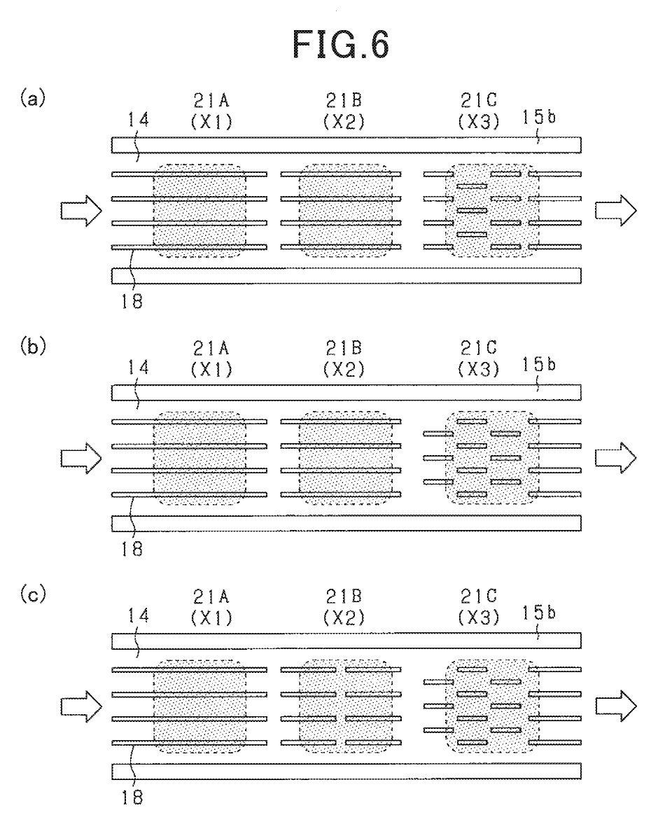

In the present embodiment, the cooling part 13 of the power conversion device 10 is configured as illustrated in FIG. 6. In this case, at the heat generating portion on the downstream side, the number of fins in the refrigerant circulation direction is larger than that on the upstream side, and in rows of the fins 18 in the refrigerant circulation direction, the fin 18 of a rear row is disposed between the fins 18 of a front row in the refrigerant circulation direction. The configuration illustrated in FIG. 6 will be described specifically.

In FIG. 6(a), (b), as in FIG. 2, the first and second fin groups 21A, 21B at the heat generating portions X1, X2 on the upstream side and the third fin group 21C on the heat generating portion X3 on the downstream side differ in fin structure. Specifically, in the present embodiment, in the third fin group 21C, since the number of in the refrigerant circulation direction is larger than those in the other fin groups, the length of the fin 18 is shorter, and the fins 18 are arranged alternately in the rows in the refrigerant circulation direction.

In FIG. 6(a), in the third fin group 21C, the fins 18 in the first row (the fin row on the uppermost stream side) are disposed on the extended lines of the fins 18 of the second fin group 21B, the fins 18 in the second row are disposed between the fins 18 in the first row, and the fins 18 in the third row are disposed between the fins 18 in the second row. It is noted that although the fins 18 in the first row and the third row are disposed on the extended lines of the fins 18 of the second fin group 21B, the fins 18 in the third row may deviate from the extended lines of the fins 18 of the second fin group 21B. The fins 18 in the fourth row are provided as straight fins on the downstream side with respect to the heat generating portion X3. In addition, in FIG. 6(b), although the arrangement patterns of the first row to the third row are changed, the fins are arranged alternately in the rows as in FIG. 6(a).

In addition, in FIG. 6(c), in the three fin groups 21A to 21C, fin structures are different from each other, and the numbers of divisions of the fin (the number of fins) in the refrigerant circulation direction are different from each other. In this case, the fin group closer to the downstream side has a larger number of divisions of the fin (the number of fins). In addition, in the third fin group 21C, the fins 18 are arranged alternately in the rows in the refrigerant circulation direction.

According to the configuration of the present embodiment, when the refrigerant flows into the third fin group 21C in the refrigerant flow passage 14, the refrigerant impacts the fins 18, whereby a turbulent flow easily occurs. Hence, the cooling efficiency in the third fin group 21C can be increased.

In addition, in the configuration illustrated in FIG. 6(c), with respect to the second fin group 21B at the intermediate position, the cooling efficiency of the first fin group 21A on the uppermost stream side can be decreased, and the cooling efficiency of the third fin group 21C on the lowermost stream side can be increased. Hence, a configuration suitable for equalizing the degrees of cooling the reactors 12A to 12C of the power conversion device 10 can be achieved.

### (Third embodiment)

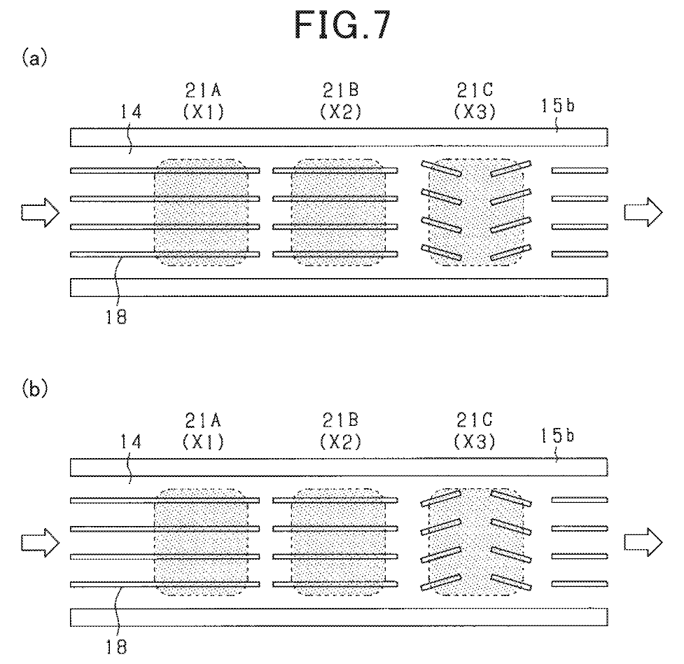

In the present embodiment, the cooling part 13 of the power conversion device 10 is configured as illustrated in FIG. 7. In this case, at the heat generating portion on the downstream side, the fins 18 are provided in the direction intersecting with the fins 18 provided at the heat generating portion on the upstream side. The configuration illustrated in FIG. 7 will be described specifically.

In FIG. 7(a), (b), as in FIG. 2, the first and second fin groups 21A, 21B at the heat generating portions X1, X2 on the upstream side and the third fin group 21C at the heat generating portion X3 on the downstream side differ in fin structure. Specifically, in the present embodiment, in the third fin group 21C, the fins 18 are provided in the direction intersecting with the fins 18 of the first and second fin groups 21A, 21B. In other words, the fins 18 of the third fin group 21C are provided at an angle with respect to the fins 18 of the first and second fin groups 21A, 21B. In this case, the fins 18 of the third fin group 21C are provided so as to block the refrigerant passing through the first and second fin groups 21A, 21B, whereby the cooling efficiency at the heat generating portion X3 is increased.

In addition, in the third fin group 21C, the directions of the fins 18 differ between the first row (front row) and the second row (rear row). Hence, in the third fin group 21C, the flow direction of the refrigerant is changed at a plurality of portions, whereby the cooling efficiency is increased. It is noted that, in the third fin group 21C, as in the first and second fin groups 21A, 21B, the directions of the fins 18 in the last row (the fins 18 on the downstream side with respect to the heat generating portion X3) are parallel to the peripheral wall part 15b of the flow passage formation part 15 (i.e., the direction in which the heat generating portions X1 to X3 are arranged).

According to the configuration of the present embodiment, the refrigerant flowing through the refrigerant flow passage 14 easily impacts plate surfaces of the fins 18, whereby the cooling efficiency can be increased in the third fin group 21C.

### (Fourth embodiment)

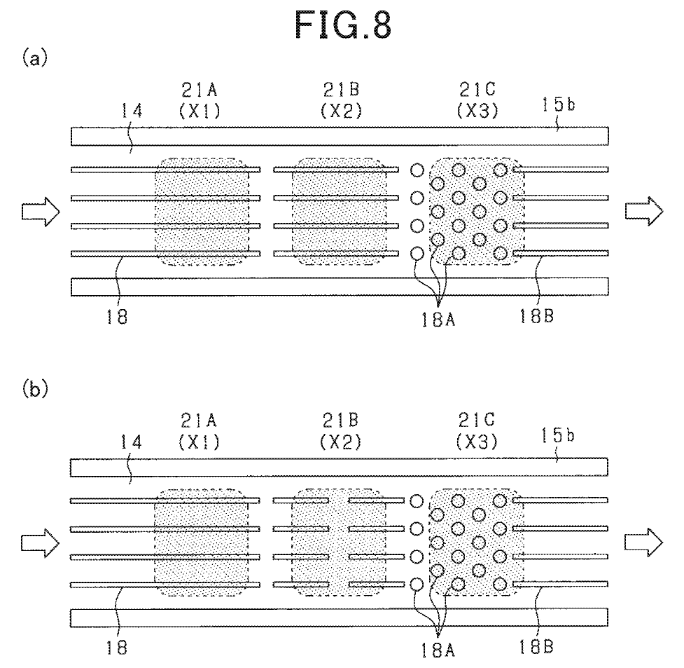

In the present embodiment, the cooling part 13 of the power conversion device 10 is configured as illustrated in FIG. 8. In this case, at the heat generating portion on the upstream side, the fins 18 having an elongated plate shape extending from the upstream side toward the downstream side are provided in the refrigerant flow passage. In contrast, at the heat generating portion on the downstream side, fins having a pin shape are provided side by side in the refrigerant circulation direction.

In FIG. 8(a), as the fins 18 of the third fin group 21C, pin fins 18A having a pin shape and flat plate fins 18B having a flat plate shape are provided. The cross section of the pin fin 18A has a circular shape, which is a perfect circle shape or an ellipse shape. If the cross section of the pin fin 18A is an ellipse, the pin fin 18A needs to be disposed so that the direction of the long diameter matches the refrigerant circulation direction. The diameter of the pin fin 18A (in the case of an ellipse, the short diameter) needs to be larger than the plate thickness of the fin 18 having a flay plate shape. It is noted that the cross section of the pin fin 18A may be other than the circular shape, and may be a semicircle shape whose arc faces the upstream side or have a polygonal shape having three or more sides.

The pin fins 18A are provided on the upstream side of the heat generating portion X3, and the flat plate fins 18B are provided on the downstream side of the heat generating portion X3. The pin fins 18A are provided in a state of a plurality of rows side by side in the refrigerant circulation direction. In the heat generating portion X3, the pin fins 18A are arranged at alternate positions in the rows in the refrigerant circulation direction. Since the pin fins 18A are used as the fins 18, the number of fins separated from each other in the refrigerant circulation direction can be increased, and the number of fins at the heat generating portion X3 on the downstream side can be larger than the numbers of fins at the heat generating portions X1, X2 on the upstream side. When the total surface areas of the fins 18 at the heat generating portions X1 to X3 are compared, it is necessary that the total surface area of the fins 18 at the heat generating portion X3 is the largest.

In addition, in FIG. 8(b), as in FIG. 8(a), in the third fin group 21C, the pin fins 18A and the flat plate fins 18B are provided, and, in the second fin group 21B, the fins 18 are divided into two in the refrigerant circulation direction.

According to the configuration of the present embodiment, increasing the number of fins in the refrigerant circulation direction at the heat generating portion X3 on the downstream side more than those at the heat generating portions X1, X2 on the upstream side can increase the cooling efficiency in the third fin group 21C.

### (Other embodiments)

The above embodiments may be modified, for example, as below.

In the above embodiments, the configuration is assumed in which the base part 11 has three heat generating portions in the power conversion device 10. This may be changed to a configuration having two heat generating portions or a configuration having four or more heat generating portions. For example, in the configuration having four or more heat generating portions, it is necessary that, at least at the heat generating portion on the lowermost stream side (the fourth heat generating portion), the fin configuration differs from that at the heat generating portion on the uppermost side, and the number of fins in the refrigerant circulation direction is larger. In this case, when the heat generating portion on the uppermost stream side and the heat generating portion on the lowermost stream side are compared, it is necessary that, at the heat generating portion on the lowermost stream side, the number of fins in the refrigerant circulation direction is larger than that at the heat generating portion on the uppermost stream side, and adjacent heat generating portions at which the numbers of fins in the refrigerant circulation direction are the same may be included. In addition, in the configuration having the heat generating portions, the number of which is n, along the refrigerant circulation direction, at i-th (i = 1 to n-1) and (i+1)-th heat generating portions from the uppermost stream side, the number of fins at the (i+1)-th heat generating portion in refrigerant circulation direction needs to be equal to or larger than that at the i-th heat generating portion.

For example, in the configuration having four heat generating portions, at one heat generating portion on the upstream side, two heat generating portions on the upstream side, or three heat generating portions on the upstream side, which includes the heat generating portion on the uppermost stream side, each of the fin groups 21 needs not to be divided in the refrigerant circulation direction, and at the remaining heat generating portions including the heat generating portion on the lowermost side, each of the fin groups 21 needs to be divided in the refrigerant circulation direction. Hence, the refrigerant temperature can be suppressed from increasing at the heat generating portion on the upstream side, and at the heat generating portion on the downstream side, the decrease of the cooling capability due to the increase of the temperature on the upstream side can be compensated for by the increase of the cooling capability caused by blocking the growth of the boundary layer.

In the cooling part 13 of the power conversion device 10, a corner part may be provided in the refrigerant flow passage 14, or a folding (U-turn part) may be provided in the refrigerant flow passage 14. Also according to this configuration, fin structures need to be differentiated between the heat generating portion on the upstream side and the heat generating portion on the downstream side, and the number of fines in the refrigerant circulation direction needs to be made larger at the heat generating portion on the downstream side than that at the heat generating portion on the upstream side.

The power conversion device may be an inverter having a plurality of switching devices. In this case, semiconductor switching elements (switching devices) provided to the inverter need to be heat generating components, and the heat generating components need to be cooled as a target to be cooled.

The power conversion device of the present disclosure may be used for not only a power supply system for a vehicle but also a power supply system for another movable body such as a flying body or a boat. In addition, the power conversion device may be used for a stationary power supply system.

In order to solve the problem described above, the power conversion device of the present disclosure is a power conversion device (10) having a plurality of heat generating components (12) that are mounted to a base part (11), which is a component mounting part, side by side, and a cooling part (13) that is integrally provided to the base part and cools the plurality of heat generating components, wherein the cooling part has a flow passage formation part (15) that forms a refrigerant flow passage (14) in a direction in which the plurality of heat generating components are arranged, and a fin (18) that extends from an upstream side to a downstream side in the refrigerant flow passage, portions corresponding to the heat generating components in the base part are respectively heat generating portions, and the heat generating portion on the upstream side and the heat generating portion on the downstream side of the heat generating portions in the cooling part differ in fin structure, and at the heat generating portion on the downstream side, the number of fins separated from each other in a refrigerant circulation direction is larger than that at the heat generating portion on the upstream side.

In the power conversion device, when the plurality of heat generating components are cooled in predetermined order by a refrigerant flowing through the refrigerant flow passage of the cooling part, there is a concern that the cooling capability of the heat generating components on the downstream side of the refrigerant flow passage becomes lower than that of the heat generating components on the upstream side of the refrigerant flow passage. Focusing on this point, of the heat generating portions corresponding to the heat generating components, fin structures are differentiated between the heat generating portion on the upstream side and the heat generating portion on the downstream side, and the number of fines separated from each other in the refrigerant circulation direction is made larger at the heat generating portion on the downstream side than at the heat generating portion on the upstream side. Hence, the cooling efficiency of the heat generating portion on the downstream is increased compared with that at the heat generating portion on the upstream side. As a result, in the power conversion device having the plurality of heat generating components, the heat generating components can be appropriately cooled.

It is noted that, in the cooling part, of the plurality of heat generating portions arranged along the refrigerant flow passage, when the heat generating portion on the uppermost stream side and the heat generating portion on the lowermost stream side are compared, it is necessary that, at the heat generating portion on the lowermost stream side, the number of fins in the refrigerant circulation direction is larger than that at the heat generating portion on the uppermost stream side. In addition, of the plurality of heat generating portions arranged along the refrigerant flow passage, adjacent heat generating portions at which the numbers of fins in the refrigerant circulation direction are the same may be included.

Hereinafter, technical ideas extracted from the embodiments described above will be described.

### [Configuration 1]

A power conversion device (10) having a plurality of heat generating components (12) that are mounted to a base part (11), which is a component mounting part, side by side, and a cooling part (13) that is integrally provided to the base part and cools the plurality of heat generating components, wherein the cooling part has a flow passage formation part (15) that forms a refrigerant flow passage (14) in a direction in which the plurality of heat generating components are arranged, and a fin (18) that extends from an upstream side to a downstream side in the refrigerant flow passage, portions corresponding to the heat generating components in the base part are respectively heat generating portions, and the heat generating portion on the upstream side and the heat generating portion on the downstream side of the heat generating portions in the cooling part differ in fin structure, and at the heat generating portion on the downstream side, the number of fins separated from each other in a refrigerant circulation direction is larger than that at the heat generating portion on the upstream side.

### [Configuration 2]

The power conversion device according to configuration 1, wherein at the heat generating portion on the downstream side, the number of fins in the refrigerant circulation direction is larger than that on the upstream side, and a length of the fin in the refrigerant circulation direction is shorter than that of the fins on the upstream side.

### [Configuration 3]

The power conversion device according to configuration 1 or 2, wherein in the cooling part, at each of the heat generating portions, the plurality of fins are provided side by side in a width direction of the refrigerant flow passage, and at the heat generating portion on the downstream side, the number of fins in the refrigerant circulation direction is larger than that on the upstream side, and in rows of the fins in the refrigerant circulation direction, the fin of a rear row is disposed between the fins of a front row in the refrigerant circulation direction.

### [Configuration 4]

The power conversion device according to configuration 1 or 2, wherein at the heat generating portion on the downstream side, the fin is provided in a direction intersecting with the fin provided at the heat generating portion on the upstream side.

### [Configuration 5]

The power conversion device according to any of configurations 1 to 3, wherein at the heat generating portion on the upstream side, the fin having an elongated plate shape extending from the upstream side toward the downstream side is provided in the refrigerant flow passage, whereas at the heat generating portion on the downstream side, the fins having a pin shape are provided side by side in the refrigerant circulation direction.

### [Configuration 6]

The power conversion device according to any of configurations 1 to 5, wherein at least three heat generating components are mounted to the base part side by side, and in the cooling part, the number of fins in the refrigerant circulation direction increases in order of the heat generating portion (X1) on the uppermost stream side, the heat generating portion (X2) at an intermediate position between the uppermost stream side and the lowermost stream side, and the heat generating portion (X3) on the lowermost stream side.

### [Configuration 7]

The power conversion device according to any of configurations 1 to 6, further having a plurality of reactors (12A to 12C) as the heat generating components, wherein

the plurality of reactors are arranged side by side in order from the upstream side of the refrigerant flow passage to the downstream side thereof, on a surface opposite to a surface, on which the cooling part is provided, of the base part.

The present disclosure has so far been described based on embodiments. However, the present disclosure should not be construed as being limited to these embodiments or the structures. The present disclosure should encompass various modifications, and modifications within the range of equivalence. In addition, various combinations and modes, as well as other combinations and modes, including those which include one or more additional elements, or those which include fewer elements should be construed as being within the scope and spirit of the present disclosure.

What is claimed is:

1. A power conversion device having a plurality of heat generating components that are mounted to a base part, which is a component mounting part, side by side, and a cooling part that is integrally provided to the base part and cools the plurality of heat generating components, wherein
the cooling part has a flow passage formation part that forms a refrigerant flow passage in a direction in which the plurality of heat generating components are arranged, and fins having a long shape that extends from an upstream side to a downstream side in the refrigerant flow passage,
the fins are provided in a width direction of the refrigerant flow passage in a state of a plurality of rows,
portions corresponding to the heat generating components in the base part are respectively heat generating portions,
the heat generating portion on the upstream side and the heat generating portion on the downstream side of the heat generating portions in the cooling part differ in fin structure,
at the heat generating portion on the upstream side, the fins in each row are provided without being divided at a position in the heat generating portion in a refrigerant circulation direction, and
at the heat generating portion on the downstream side, the fins in each row are divided at a position in the heat generating portion in the refrigerant circulation direction, so that the number of fins in the refrigerant circulation direction is larger than that at the heat generating portion on the upstream side, and a length of the fin in the refrigerant circulation direction is shorter than that of the fin at the heat generating portion on the upstream side.

2. The power conversion device according to claim 1, wherein
at the heat generating portion on the downstream side, the fin is provided in a direction intersecting with the fin provided at the heat generating portion on the upstream side.

3. The power conversion device according to claim 1, wherein
at least three heat generating components are mounted to the base part side by side, and
in the cooling part, the number of fins in the refrigerant circulation direction increases in order of the heat generating portion on the uppermost stream side, the heat generating portion at an intermediate position between the uppermost stream side and the lowermost stream side, and the heat generating portion on the lowermost stream side.

4. The power conversion device according to claim 1, further having a plurality of reactors as the heat generating components, wherein
the plurality of reactors are arranged side by side in order from the upstream side of the refrigerant flow passage to the downstream side thereof, on a surface opposite to a surface, on which the cooling part is provided, of the base part.
